(19) United States
(12) Patent Application Publication
(10) Pub. No.: US 2024/0315111 A1
(43) Pub. Date: Sep. 19, 2024

(54) OLED DISPLAY MODULE AND DISPLAY DEVICE

(71) Applicants: CHENGDU BOE OPTOELECTRONICS TECHNOLOGY CO., LTD., Chengdu, Sichuan (CN); BOE TECHNOLOGY GROUP CO., LTD., Beijing (CN)

(72) Inventors: Haotian Yang, Beijing (CN); Xiaoxia Liu, Beijing (CN); Kang Wang, Beijing (CN); Xiangdong Wei, Beijing (CN); Zheng Bao, Beijing (CN); Jiaming Shen, Beijing (CN); Miaomiao Song, Beijing (CN); Seungyong Oh, Beijing (CN)

(73) Assignees: CHENGDU BOE OPTOELECTRONICS TECHNOLOGY CO., LTD., Chengdu, Sichuan (CN); BOE TECHNOLOGY GROUP CO., LTD., Beijing (CN)

(21) Appl. No.: 18/027,216

(22) PCT Filed: Jun. 14, 2022
(86) PCT No.: PCT/CN2022/098635

§ 371 Date: Mar. 20, 2023

(51) Int. Cl. H10K 59/80

(52) U.S. Cl. CPC H10K 59/8722

(57) ABSTRACT

This disclosure relates to an organic light-emitting diode (OLED) display module, including a middle bezel, a display panel, and a cover glass. The cover glass is located at a light-emitting side of the display panel and the middle bezel includes a side plate surrounding the display panel and the cover glass. A side surface of the cover glass is a first inclined surface inclined at an angle to a light incident surface of the cover glass, and the side plate includes a second inclined surface inclined correspondingly and being attached to the first inclined surface. This disclosure also relates to a display device.

### TECHNICAL FIELD

The present disclosure relates to the technical field of display product manufacturing, and more particularly, relates to an organic light-emitting diode (OLED) display module and a display device.

### BACKGROUND

Conventionally, an active-matrix organic light-emitting diode (AMOLED) watch module is attached to a complete machine mainly by attaching a cover glass to a middle bezel, and a common design is to overlap an edge of the cover glass onto the middle bezel, and attach them together by means of a double-sided adhesive tape with a thickness of about 1 mm. The middle bezel can support the module well by being attached to the cover glass. Because of the fitting tolerance of the module and the assembly tolerance of attaching the middle bezel, the distance between the middle bezel and a module panel is generally 0.6 mm. The attaching mode of the middle bezel and the cover glass and the distance between the middle bezel and the module panel impede the realization of a narrow bezel.

### SUMMARY

In order to solve the above technical problem, the present disclosure provides an OLED display module and a display device, which solve the problem that a narrow bezel cannot be further realized due to the limitation of the attachment between the middle bezel and the cover glass and the distance between the middle bezel and the module panel.

In order to achieve the above object, embodiments of the present disclosure adopt the following technical solutions. An OLED display module includes a middle bezel, a display panel, and a cover glass, wherein the cover glass is located at a light-emitting side of the display panel, and the middle bezel includes a side plate surrounding the display panel and the cover glass, wherein
a side surface of the cover glass is a first inclined surface inclined at an angle to a light incident surface of the cover glass, and the side plate includes a second inclined surface inclined correspondingly and being attached to the first inclined surface.

Optionally, the angle between the first inclined surface and the light incident surface of the cover glass is 30 degrees to 60 degrees.

Optionally, the first inclined surface and the second inclined surface are both planar structures.

Optionally, the first inclined surface is provided with a concave-convex structure, and the second inclined surface is provided with a concave-convex structure fitting the concave-convex structure of the first inclined surface.

Optionally, the concave-convex structures are stripe structures extending in a first direction, and the first direction is parallel to an extension direction of the first inclined surface.

Optionally, a cross-sectional shape of the concave-convex structures in a direction perpendicular to the first inclined surface is at least one of arc, rectangle, trapezoid, or triangle.

Optionally, the side plate further includes a support surface connected to the second inclined surface, the support surface supports the cover glass on a side of the cover glass close to the display panel, and the support surface is disposed parallel to the light incident surface of the cover glass.

Optionally, the side plate further include a first end surface connected to the second inclined surface, the first end surface is located on a side of the second inclined surface away from the display panel, and the first end surface is flush with a light-emitting surface of the cover glass.

Optionally, the display panel includes a display region and a non-display region, and the non-display region includes a bonding area located at a side of the display region and a non-bonding area located differently from the bonding area;
the cover glass includes a first region corresponding to the bonding area, a side surface of the first region is the first inclined surface, the side plate includes a first sub-side plate corresponding to the bonding area, and the first sub-side plate includes the second inclined surface inclined correspondingly and being attached to the first inclined surface; and
the side plate includes a second sub-side plate corresponding to the non-bonding area, and in a direction perpendicular to the display panel, the second sub-side plate includes a first portion attached to the cover glass and a second portion adjacent to the first portion, and a filling structure is filled between the second portion, the cover glass, and the display panel.

Optionally, a length of the bonding area in an extension direction of the bonding area is less than a length of the first sub-side plate in an extension direction of the first sub-side plate.

Optionally, the second sub-side plate further includes a third portion located on a side of the second portion away from the first portion, and in a direction parallel to the display panel, the third portion is disposed protruding in a direction toward the display panel, and a side of the filling structure away from the cover glass is attached to the third portion.

Optionally, the third portion is located on a backlight side of the display panel in the direction perpendicular to the display panel.

Optionally, an orthographic projection of the third portion onto the cover glass adjoins an orthographic projection of the display panel onto the cover glass, or the orthographic projection of the third portion onto the cover glass partially overlaps with the orthographic projection of the display panel onto the cover glass.

Optionally, in a direction from the middle bezel to the display panel, a width of a first attaching surface of the filling structure that is attached to the third portion is 0.8 mm to 1 mm.

Optionally, in the direction parallel to the display panel, a part of the filling structure extends in a direction toward the display panel, to form a support portion supporting the display panel on a backlight side of the display panel.

Optionally, a width of the support portion is 1 mm to 1.8 mm in the direction from the middle bezel to the display panel.

Optionally, in the direction parallel to the display panel, a part of the filling structure extends in the direction toward the display panel, to form a filling portion filled between the cover glass and the display panel.

Optionally, an adhesive glue layer is provided between the display panel and the cover glass, and a thickness of the adhesive glue layer is the same as that of the filling portion in the direction perpendicular to the display panel.

Optionally, the filling structure has a thickness of 0.8 mm to 1.6 mm in the direction perpendicular to the display panel.

Optionally, the first sub-side plate further includes a first end surface connected to the second inclined surface, and the first end surface is located on a side of the second inclined surface away from the display panel;
a second end surface of the first portion is flush with the light-emitting surface of the cover glass, and a width of the first end surface is the same as that of the second end surface in a direction parallel to the cover glass.

Optionally, the filling structure is made of a curable polymer material.

Embodiments of the present disclosure also provide a display device, including the above OLED display module.

Beneficial effects of the present disclosure are: the cover glass and the side plate are attached together by means of inclined surfaces, thus the width of the bezel is reduced while a sufficient attachment area is ensured to guarantee the attachment strength.

### BRIEF DESCRIPTION OF THE DRAWINGS

FIG. 1 is a schematic structural diagram of a display module in the related art;

FIG. 2 is another schematic structural diagram of a display module in the related art;

FIG. 3 is a schematic structural diagram of a display module according to an embodiment of the present disclosure;

FIG. 4 is a schematic structural diagram of a cover glass according to an embodiment of the present disclosure;

FIG. 5 is another schematic structural diagram of a cover glass according to an embodiment of the present disclosure;

FIG. 6 is still another schematic structural diagram of a cover glass according to an embodiment of the present disclosure;

FIG. 7 is another schematic structural diagram of a display module according to an embodiment of the present disclosure;

FIG. 8 is still another schematic structural diagram of a display module according to an embodiment of the present disclosure;

FIG. 9 is yet another schematic structural diagram of a cover glass according to an embodiment of the present disclosure;

FIG. 10 is a schematic diagram of an assembled state of a cover glass and a display panel according to an embodiment of the present disclosure;

FIG. 11 is a schematic cross-sectional diagram of the structure in FIG. 10;

FIG. 12 is a schematic diagram of a formation state of a filling structure according to an embodiment of the present disclosure;

FIG. 13 is an enlarged view of a portion in FIG. 12.

### DETAILED DESCRIPTION

In order to make the objects, technical solutions, and advantages of the present disclosure more apparent, technical solutions of the embodiments of the present disclosure will be described clearly and thoroughly with reference to the drawings. The embodiments described are merely part of, but not all, embodiments of the present disclosure. Based on the embodiments in the present disclosure, all other embodiments obtained by those skilled in the art are within the scope of the present disclosure.

In the description of the present disclosure, it should be noted that the terms “central”, “upper”, “lower”, “left”, “right”, “vertical”, “horizontal”, “inner”, “outer”, and the like indicate orientations or positional relationships based on the orientations or positional relationships shown in the drawings, and are merely intended to facilitate description of the present disclosure and simplify the description, and do not indicate or imply that the referenced devices or elements must have a particular orientation, or be constructed and operated in a particular orientation, and thus should not be construed as limiting the present disclosure. Furthermore, the terms “first”, “second”, and “third” are for descriptive purposes only and are not to be construed as indicating or implying relative importance.

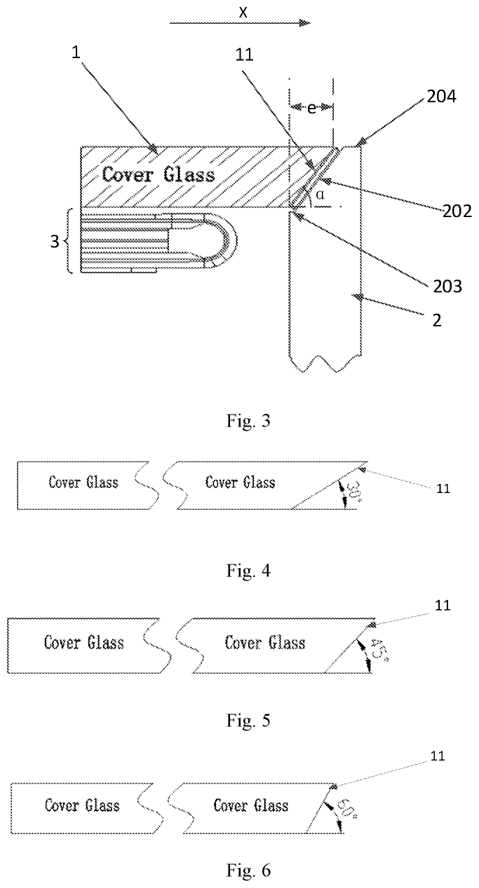

Referring to FIG. 3 to FIG. 5, an embodiment of the present disclosure provides an OLED display module, including a middle bezel 2, a display panel 3, and a cover glass 1, wherein the cover glass 1 is located at a light-emitting side of the display panel 3, and the middle bezel 2 includes a side plate surrounding the display panel 3 and the cover glass 1, wherein a side surface of the cover glass 1 is a first inclined surface inclined at an angle to a light incident surface of the cover glass 1, and the side plate includes a second inclined surface inclined correspondingly and being attached to the first inclined surface.

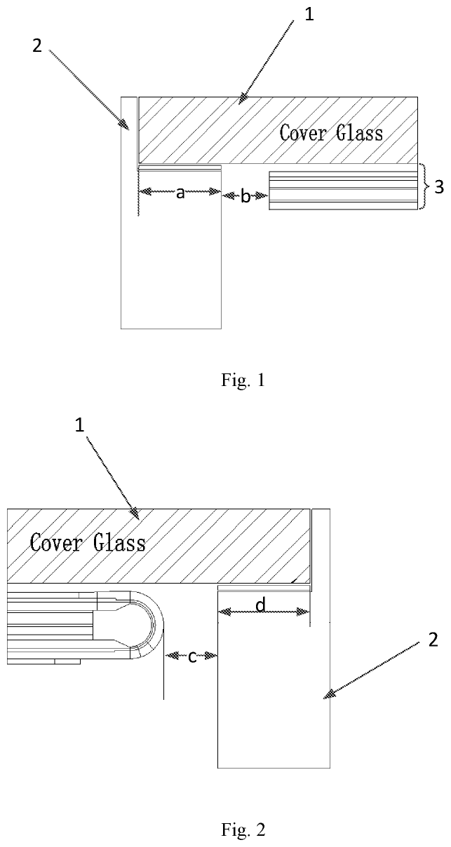

Referring to FIG. 1 and FIG. 2, the display panel 3 includes a display region and a non-display region, and the non-display region includes a bonding area located at a side of the display region and a non-bonding area located differently from the bonding area. FIG. 1 shows an attachment between the middle bezel and the cover glass in the non-bonding area in the related art, and FIG. 2 shows an attachment between the middle bezel and the cover glass in the bonding area in the related art. With regard to the attachment between the middle bezel 2 and the cover glass 1, the middle bezel 2 includes an attachment support portion supporting the cover glass 1 on the backlight side of the cover glass 1. In order to ensure the support strength, lengths a and d of the attachment support portion are both 1 mm in the direction parallel to the cover glass 1. Considering fitting tolerances, to avoid interference between the middle bezel 2 and the display panel 3, there is a gap between the attachment support portion and the display panel 3, and the widths b and c of the gap are generally 0.6 mm in the direction parallel to the cover glass 1. In FIG. 1 and FIG. 2, whether in the bonding area or in the non-bonding area, the attachment between the middle bezel 2 and the cover glass 1 is a planar attachment, i.e., the light incident surface of the cover glass 1 is attached to the attachment support portion of the middle bezel 2, and the attaching surface of the attachment support portion that is attached to the backlight surface of the cover glass is a plane parallel to the light incident surface of the cover glass. In the present embodiment, the attachment between the cover glass 1 and the middle bezel 2 is changed to an inclined-surface attachment. Referring to FIG. 3, while ensuring that there is a sufficient attachment area between the cover glass 1 and the middle bezel 2, the width e of the first inclined surface in the direction parallel to the light incident surface of the cover glass 1 is reduced. In an implementation, the width e of the first inclined surface in the direction parallel to the light incident surface of the cover glass 1 is 0.4 mm to 0.6 mm, e.g., the width e may be 0.5 mm, which realizes a narrow bezel compared with 1 mm in FIG. 1 and FIG. 2.

In an exemplary implementation, the angle between the first inclined surface 11 and the light incident surface of the cover glass 1 is 30 degrees to 60 degrees, but the present disclosure is not limited thereto.

In an exemplary implementation, the angle between the first inclined surface 11 and the light incident surface of the cover glass 1 is 25 degrees to 35 degrees, and in FIG. 4, the angle between the first inclined surface 11 and the light incident surface of the cover glass 1 is 30 degrees.

In an exemplary implementation, the angle between the first inclined surface 11 and the light incident surface of the cover glass 1 is 40 degrees to 50 degrees, and in FIG. 5, the angle between the first inclined surface 11 and the light incident surface of the cover glass 1 is 45 degrees.

In an exemplary implementation, the angle between the first inclined surface 11 and the light incident surface of the cover glass 1 is 55 degrees to 65 degrees, and in FIG. 6, the angle between the first inclined surface 11 and the light incident surface of the cover glass 1 is 60 degrees.

In an exemplary implementation, the first inclined surface and the second inclined surface are both planar structures.

In an exemplary implementation, the first inclined surface is provided with a concave-convex structure, and the second inclined surface is provided with a concave-convex structure fitting the concave-convex structure of the first inclined surface.

In an exemplary implementation, the concave-convex structures are stripe structures extending in a first direction, and the first direction is parallel to an extension direction of the first inclined surface.

It should be noted that the shape of the display module may be a regular geometric shape or a special shape, for example, if the display module is circular, then the cover glass 1 is circular, and the first direction is the circumferential direction of the cover glass 1; if the display module is rectangular, then the cover glass 1 is rectangular, and the first direction is the extension direction of the side edge of the cover glass corresponding to the first inclined surface.

It should be noted that the first inclined surface may be arranged at all the side surfaces of the cover glass, or arranged at some of the side surfaces of the cover glass, as long as a narrow bezel can be realized. In case that the first inclined surface is some of the side surfaces of the cover glass, the first direction is the extension direction of the some side surfaces, and the first direction is perpendicular to the light incident surface of the cover glass.

In an exemplary implementation, the concave-convex structure on the first inclined surface fits the concave-convex structure on the second inclined surface, and the concave-convex structure may be regularly distributed on the first inclined surface or may be dispersedly distributed on the first inclined surface.

In an exemplary implementation, a cross-sectional shape of the concave-convex structures in the direction perpendicular to the first inclined surface is at least one of arc, rectangle, trapezoid, or triangle, but the present disclosure is not limited thereto.

In case that the concave-convex structure includes at least two convex portions or at least two concave portions, the cross-sectional shapes of the at least two convex portions or the at least two concave portions in the direction perpendicular to the first inclined surface may be the same or different.

In an exemplary implementation, the side plate further includes a support surface 203 connected to the second inclined surface 202, the support surface 203 supports the cover glass 1 on a side of the cover glass I close to the display panel 3, and the support surface 203 is disposed parallel to the light incident surface of the cover glass 1.

The support surface 203 is connected to an end of the second inclined surface 202 close to the display panel 3, the second inclined surface 202 is attached to the first inclined surface 11 of the cover glass 1 through an adhesive glue layer, and the support surface 203 plays a role of positioning the adhesive glue layer and plays a role of positioning the attachment between the cover glass 1 and the middle bezel 2.

Illustratively, in the direction parallel to the cover glass 1, the support surface 203 has a width of 0.2 mm to 0.5 mm, but the present disclosure is not limited thereto.

In an exemplary implementation, the side plate further includes a first end surface 204 connected to the second inclined surface 202, the first end surface is located on a side of the second inclined surface 202 away from the display panel, and the first end surface is flush with the light-emitting surface of the cover glass 1.

The first end surface being flush with the light-emitting surface of the cover glass 1 ensures the overall flatness of the light-emitting surface of the display module.

In the direction parallel to the cover glass 1, the first end surface 204 has a width of 0.2 mm to 0.4 mm, but the present disclosure is not limited thereto.

In an implementation, in order to achieve a narrow bezel, the width of the support surface 203 is 0.2 mm and the width of the first end surface 204 is 0.2 mm, i.e., in the direction parallel to the cover glass 1, a sum of the widths of the support surface 203, the first end surface 204, and the first inclined surface 11 is less than the width of the middle bezel in FIG. 1 and FIG. 2, but the present disclosure is not limited thereto.

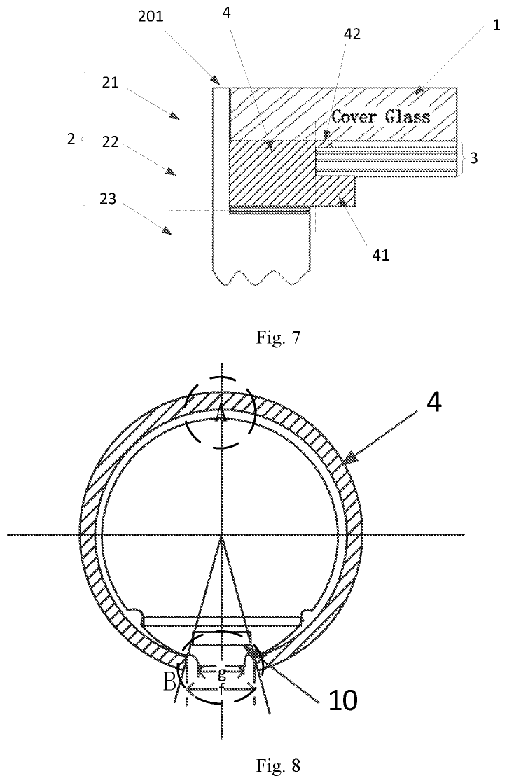

Referring to FIG. 7 and FIG. 8, in an exemplary implementation, the display panel includes a display region and a non-display region, and the non-display region includes a bonding area 10 located at a side of the display region and a non-bonding area located differently from the bonding area 10;

the cover glass 1 includes a first region corresponding to the bonding area 10, a side surface of the first region is the first inclined surface 11, the side plate includes a first sub-side plate corresponding to the bonding area 10, and the first sub-side plate includes the second inclined surface inclined correspondingly and being attached to the first inclined surface 11; and
the side plate includes a second sub-side plate corresponding to the non-bonding area, and in the direction perpendicular to the display panel, the second sub-side plate includes a first portion 21 attached to the cover glass 1, and a second portion 22 adjacent to the first portion 21, and a filling structure 4 is filled between the second portion 22, the cover glass 1, and the display panel 3.

In this implementation, FIG. 3 is a schematic diagram of a cross-section of the display module in the direction perpendicular to the cover glass and corresponding to the bonding area, and FIG. 7 is a schematic diagram of a cross-section of the display module in the direction perpendicular to the cover glass and corresponding to the non-bonding area. Referring to FIG. 8, FIG. 3 can be a schematic cross-sectional diagram of region B in the direction perpendicular to the cover glass, and FIG. 7 is a schematic cross-sectional diagram of region A in the direction perpendicular to the cover glass.

Referring to FIG. 1, in the related art, as to the non-bonding area, the middle bezel 2 is attached to the cover glass 1, and the middle bezel 2 includes an attachment support portion 41 supporting the cover glass 1 on the backlight side of the cover glass 1. In order to ensure the support strength, the length a of the attachment support portion 41 is 1 mm in the direction parallel to the cover glass 1, and in order to avoid interference between the middle bezel 2 and the display panel 3, considering fitting tolerances, there is a gap between the attachment support portion 41 and the display panel 3. The width b of the gap is generally 0.6 mm in the direction parallel to the cover glass 1. In this embodiment, a filling structure 4 is additionally provided between the cover glass 1, the display panel 3, and the middle bezel 2, which changes the attachment mode of the middle bezel 2 and the cover glass 1, so that the middle bezel 2 can be moved inward in the direction toward the display panel 3, thereby realizing a narrow bezel.

In an exemplary implementation, the filling structure 4 is made of a curable polymer material, for example, epoxy, silicone, and the like, but the present disclosure is not limited thereto. On the premise of ensuring the support strength, the filling structure 4 has a certain elasticity so as to play the role of sealing the display panel 3, so that the fitting tolerance of the display panel 3 can be disregarded, and a narrow bezel can be further realized.

In an exemplary implementation, the filling structure 4 may be made using an injection molding process or a 3D printing process, but the present disclosure is not limited thereto.

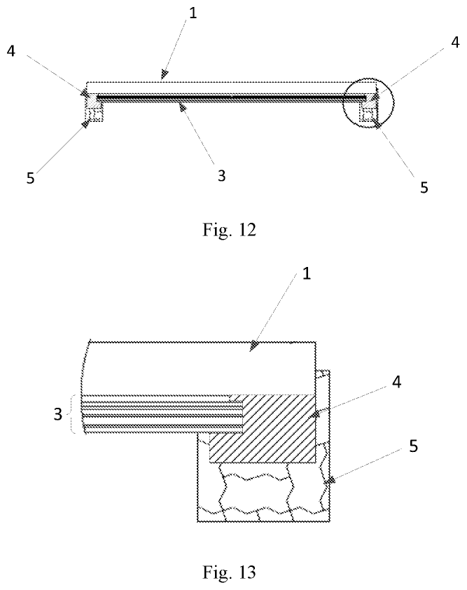

Illustratively, after the cover glass 1 and the display panel 3 are assembled, the assembled cover glass 1 and display panel 3 may be fitted with a jig, and the filling structure 4 is directly formed on the cover glass 1 and the display panel 3 through the jig 5 by using an injection molding process. FIG. 10 and FIG. 11 are schematic diagrams showing the assembled state of the cover glass 1 and the display panel 3; FIG. 11 is a schematic sectional diagram of the structure in FIG. 10; FIG. 12 is a schematic diagram of the state of forming the filling structure 4 through the jig 5; FIG. 12 is an enlarged schematic diagram of the circled portion of FIG. 11. In this way, it is not necessary to consider the fitting tolerance of the display panel 3, i.e., the distance between the middle bezel 2 and the display panel 3 can be omitted compared with FIG. 1, namely, a reduction of 0.5 mm or more can be achieved.

In an exemplary implementation, the second sub-side plate further includes a third portion 23 at a side of the second portion 22 away from the first portion 21, and in the direction parallel to the display panel 3, the third portion 23 is disposed protruding in a direction toward the display panel 3, and a side of the filling structure 4 away from the cover glass 1 is attached to the third portion 23.

In an exemplary implementation, the third portion 23 is located on the backlight side of the display panel 3 in the direction perpendicular to the display panel 3.

In the direction perpendicular to the cover glass 1, the distance between the attaching surface of the third portion 23 that is attached to the filling structure 4 and the cover glass 1 is a first distance, the distance between the backlight surface of the display panel 3 and the cover glass 1 is a second distance, and the first distance is greater than the second distance, thus avoiding interference between the middle bezel 2 and the display panel 3.

In an exemplary implementation, an orthographic projection of the third portion 23 onto the cover glass 1 adjoins an orthographic projection of the display panel 3 onto the cover glass 1, or the orthographic projection of the third portion 23 onto the cover glass 1 partially overlaps with the orthographic projection of the display panel 3 onto the cover glass 1.

Due to the arrangement of the filling structure 4, the third portion 23 is located on the backlight side of the display panel 3, and then there is no interference between the display panel 3 and the middle bezel 2 in the direction parallel to the display panel 3. The display panel 3 can extend between the third portion 23 and the cover glass 1, i.e., the orthographic projection of the third portion 23 onto the cover glass 1 partially overlaps with the orthographic projection of the display panel 3 onto the cover glass 1, and at this time, a corresponding groove can be formed in the filling structure 4 to accommodate the display panel 3, but the present disclosure is not limited thereto.

In an exemplary implementation, in the direction from the middle bezel 2 to the display panel 3, the width of the first attaching surface of the filling structure 4 that is attached to the third portion 23 is 0.8 mm to 1 mm, thereby ensuring support strength, but the present disclosure is not limited thereto.

In an exemplary implementation, in the direction parallel to the display panel 3, a part of the filling structure 4 extends in the direction toward the display panel 3, to form a support portion 41 supporting the display panel 3 on a backlight side of the display panel 3.

The arrangement of the support portion 41 may serve to support the display panel 3, and may serve to seal the display panel 3.

In an exemplary implementation, a width of the support portion 41 is 1 mm to 1.8 mm in the direction from the middle bezel 2 to the display panel 3, with reference to the X direction in FIG. 3, but the present disclosure is not limited thereto.

In an exemplary implementation, in the direction parallel to the display panel 3, a part of the filling structure 4 extends in the direction toward the display panel 3, to form a filling portion 42 filled between the cover glass 1 and the display panel 3.

The cover glass 1 and the display panel 3 are attached through the adhesive glue layer, and in some implementations, the adhesive glue layer does not completely cover the display panel 3, that is, the area of the adhesive glue layer is less than the area of the display panel 3. In this way, there is an edge area at the edge of the display panel 3 which is not covered with the adhesive glue layer, and the filling portion 42 can fill the edge area, so that there is no gap between the display panel 3 and the cover glass 1.

In an exemplary implementation, the adhesive glue layer is provided between the display panel 3 and the cover glass 1, and the thickness of the adhesive glue layer is the same as the thickness of the filling portion 42 in the direction perpendicular to the display panel 3, to ensure the attachment between the cover glass 1 and the display panel 3, and so that there is no gap between the cover glass 1 and the display panel 3, which functions to seal the display panel 3.

Illustratively, the filling portion 42 is in contact with the adhesive glue layer in the direction parallel to the display panel 3.

In an exemplary implementation, in the direction perpendicular to the display panel 3, the thickness of the filling structure 4 is 0.8 mm to 1.6 mm, but the present disclosure is not limited thereto.

In an exemplary implementation, the first sub-side plate further includes a first end surface 204 connected to the second inclined surface 202, the first end surface 204 is located on a side of the second inclined surface 202 away from the display panel 3, the second end surface 201 of the first portion 21 is flush with the light-emitting surface of the cover glass 1, and the first end surface 204 and the second end surface 201 have the same width in the direction parallel to the cover glass 1.

As to the non-bonding area, the second sub-side plate includes the first portion 21 located on the side surface of the cover glass 1, i.e., the end surface of the first portion 21 is exposed outside the cover glass 1. The arrangement of the first end surface 204 ensures the aesthetic appearance of the display module. The width of the first end surface 204 is the same as the width of the second end surface 201, so that the middle bezel 2 on the periphery of the cover glass 1 has a constant width, to ensure the aesthetic appearance.

Referring to FIG. 8, in an exemplary implementation, the length of the bonding area 10 in the extension direction of the bonding area 10 is less than the length of the first sub-side plate in the extension direction of the first sub-side plate, so as to preserve a bending space for bending a flexible printed circuit bonded to the display panel 3, to prevent interference.

Note that the extension direction of the bonding area 10 is parallel to the extension direction of a bending axis of the flexible printed circuit bonded to the display panel 3.

Illustratively, a ratio of the length of the first sub-side plate in the extension direction thereof to the length of the bonding area 10 in the extension direction thereof is 1.1 to 1.8, but the present disclosure is not limited thereto.

In an exemplary implementation, in the direction parallel to the display panel 3, if the cross-section of the display module is circular, rectangular, or special-shaped, then the display panel 3 is circular, rectangular, or special-shaped, and the like. The shape of the cover glass 1 conforms to the shape of the display panel 3, for example, with reference to FIG. 8, the display panel 3 is circular, the cover glass 1 is circular, then the middle bezel 2 is annular, and the filling structure 4 is a semi-closed annular structure provided with a notch corresponding to the bonding area 10. In the direction parallel to the display panel 3, a distance f between opposite ends of the notch of the filling structure 4 is greater than a distance g of the bonding area 10 in the first direction.

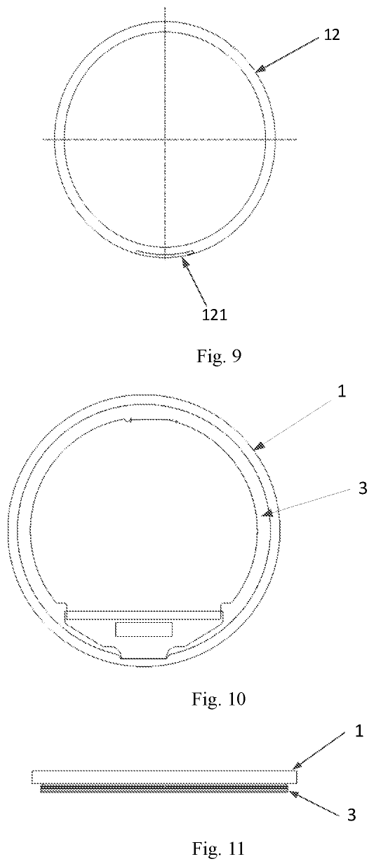

Referring to FIG. 9, the light incident surface of the cover glass 1 is provided with an ink layer 12, and the ink layer 12 is provided with a notch 121 corresponding to the first region.

Embodiments of the present disclosure also provide a display device, including the above OLED display module.

It is understood that the above implementations are merely exemplary implementations employed to illustrate the principles of the present disclosure, and that the disclosure is not limited thereto. It will be apparent to those skilled in the art that various modifications and variations can be made without departing from the spirit and essence of the present disclosure. These modifications and variations should be deemed as falling within the scope of the present disclosure.

1. An organic light-emitting diode (OLED) display module, comprising a middle bezel, a display panel, and a cover glass, wherein the cover glass is located at a light-emitting side of the display panel, and the middle bezel comprises a side plate surrounding the display panel and the cover glass, wherein
a side surface of the cover glass is a first inclined surface inclined at an angle to a light incident surface of the cover glass, and the side plate comprises a second inclined surface inclined correspondingly and being attached to the first inclined surface.

2. The OLED display module according to claim 1, wherein the angle between the first inclined surface and the light incident surface of the cover glass is 30 degrees to 60 degrees.

3. The OLED display module according to claim 1, wherein the first inclined surface and the second inclined surface are both planar structures.

4. The OLED display module according to claim 1, wherein the first inclined surface is provided with a concave-convex structure, and the second inclined surface is provided with a concave-convex structure fitting the concave-convex structure of the first inclined surface.

5. The OLED display module according to claim 4, wherein the concave-convex structures are stripe structures extending in a first direction, and the first direction is parallel to an extension direction of the first inclined surface.

6. The OLED display module according to claim 4, wherein a cross-sectional shape of the concave-convex structures in a direction perpendicular to the first inclined surface is at least one of arc, rectangle, trapezoid, or triangle.

7. The OLED display module according to claim 1, wherein the side plate further comprises a support surface connected to the second inclined surface, the support surface supports the cover glass on a side of the cover glass close to the display panel, and the support surface is disposed parallel to the light incident surface of the cover glass.

8. The OLED display module according to claim 1, wherein the side plate further comprises a first end surface connected to the second inclined surface, the first end surface is located on a side of the second inclined surface away from the display panel, and the first end surface is flush with a light-emitting surface of the cover glass.

9. The OLED display module according to claim 1, wherein the display panel comprises a display region and a non-display region, and the non-display region comprises a bonding area located at a side of the display region and a non-bonding area located differently from the bonding area;
the cover glass comprises a first region corresponding to the bonding area, a side surface of the first region is the first inclined surface, the side plate comprises a first sub-side plate corresponding to the bonding area, and the first sub-side plate comprises the second inclined surface inclined correspondingly and being attached to the first inclined surface; and
the side plate comprises a second sub-side plate corresponding to the non-bonding area, and in a direction perpendicular to the display panel, the second sub-side plate comprises a first portion attached to the cover glass and a second portion adjacent to the first portion, and a filling structure is filled between the second portion, the cover glass, and the display panel.

10. The OLED display module according to claim 9, wherein a length of the bonding area in an extension direction of the bonding area is less than a length of the first sub-side plate in an extension direction of the first sub-side plate.

11. The OLED display module according to claim 9, wherein the second sub-side plate further comprises a third portion located on a side of the second portion away from the first portion, and in a direction parallel to the display panel, the third portion is disposed protruding in a direction toward the display panel, and a side of the filling structure away from the cover glass is attached to the third portion.

12. The OLED display module according to claim 11, wherein in the direction perpendicular to the display panel, the third portion is located on a backlight side of the display panel;
and/or,
wherein an orthographic projection of the third portion onto the cover glass adjoins an orthographic projection of the display panel onto the cover glass, or the orthographic projection of the third portion onto the cover glass partially overlaps with the orthographic projection of the display panel onto the cover glass;
and/or,
wherein in a direction from the middle bezel to the display panel, a width of a first attaching surface of the filling structure that is attached to the third portion is 0.8 mm to 1 mm.

13.-14. (canceled)

15. The OLED display module according to claim 9, wherein in the direction parallel to the display panel, a part of the filling structure extends in a direction toward the display panel, to form a support portion supporting the display panel on a backlight side of the display panel.

16. The OLED display module according to claim 15, wherein a width of the support portion is 1 mm to 1.8 mm in the direction from the middle bezel to the display panel.

17. The OLED display module according to claim 15, wherein in the direction parallel to the display panel, a part of the filling structure extends in the direction toward the display panel, to form a filling portion filled between the cover glass and the display panel.

18. The OLED display module according to claim 17, wherein an adhesive glue layer is disposed between the display panel and the cover glass, and a thickness of the adhesive glue layer is the same as a thickness of the filling portion in the direction perpendicular to the display panel.

19. The OLED display module according to claim 9, wherein the filling structure has a thickness of 0.8 mm to 1.6 mm in the direction perpendicular to the display panel.

20. The OLED display module according to claim 9, wherein the first sub-side plate further comprises a first end surface connected to the second inclined surface, and the first end surface is located on a side of the second inclined surface away from the display panel;
a second end surface of the first portion is flush with a light-emitting surface of the cover glass, and a width of the first end surface is the same as a width of the second end surface in a direction parallel to the cover glass.

21. The OLED display module according to claim 9, wherein the filling structure is made of a curable polymer material.

22. A display device, comprising an OLED display module, wherein the OLED display module comprises a middle bezel, a display panel, and a cover glass, wherein the cover glass is located at a light-emitting side of the display panel, and the middle bezel comprises a side plate surrounding the display panel and the cover glass, wherein
a side surface of the cover glass is a first inclined surface inclined at an angle to a light incident surface of the cover glass, and the side plate comprises a second inclined surface inclined correspondingly and being attached to the first inclined surface.
